(19) United States
(12) Patent Application Publication
(10) Pub. No.: US 2006/0022263 A1
(43) Pub. Date: Feb. 2, 2006

(54) Selective substrate thinning for power mosgated devices

(75) Inventors: Robert P. Haase, South Wales (GB); David Paul Jones, South Glamorgan (GB)

Correspondence Address: OSTROLENK FABER GERB & SOFFEN, 1180 AVENUE OF THE AMERICAS, NEW YORK, NY, 100368403, US

(73) Assignee: International Rectifier Corporation

(21) Appl. No.: 11/194,815

(22) Filed: Aug. 1, 2005

Related U.S. Application Data
(60) Provisional application No. 60/592,609, filed on Jul. 30, 2004.

(51) Int. Cl. H01L 29/78; H01L 21/336

(52) U.S. Cl. 257/328; 257/341; 438/459; 438/268

(57) ABSTRACT

A vertical conduction semiconductor die has a top surface which receives a semiconductor junction pattern and a top electrode and a bottom surface with a bottom electrode. The bottom surface has one or more reduced thickness areas therein formed by selective etching or laser abrasion or the like to reduce the vertical conduction path length beneath at least portions of the semiconductor junction pattern and the bottom electrode to reduce the device R_{DSON}. Thickened die portions remain to strengthen the die or wafer against breakage during handling. The full wafer thickness may be reduced before the local reduced thickness portions are formed.

### RELATED APPLICATIONS

This application claims the benefit of U.S. Provisional Application No. 60/592,609, filed Jul. 30, 2004.

### FIELD OF THE INVENTION

This invention relates to MOSGATED devices and more specifically relates to the selective thinning of semiconductor device wafers to reduce R_{DSON} while maintaining wafer strength.

### BACKGROUND OF THE INVENTION

MOSGATED devices such as planar and trench power MOSFETs and IGBTs have an on-resistance which includes the drift region resistance as a component thereof. It is known to reduce the thickness of the wafer, for example, from 380μ to 80μ or less to reduce R_{DSON} as well as to obtain other benefits. Thus, most junction-forming steps are performed on the top surface of the wafer before thinning. The top surface is then covered with a protective layer and the wafer thickness is reduced by backgrinding and/or etching the full rear surface of the wafer. The back metal is then applied to the back surface.

It is very difficult to handle wafers after they are reduced in thickness to, for example, 80μ or less (over their full area) and considerable breakage is encountered in the processing steps for thinning the wafer and applying the back metal.

It would be very desirable to have a process by which wafers can be thinned to reduce drift region resistance and yet be rugged enough to withstand handling without excess breakage.

### BRIEF DESCRIPTION OF THE INVENTION

In accordance with the invention, wafers are first processed in the usual manner to form the top surface junction patterns. Such wafers are for vertical conduction devices, such as planar or trench type MOSFETs. Thereafter, the wafer thickness may be partially reduced, as by a back surface grind to a thickness which is still large enough to withstand wafer handling stress without excess breakage. The back surface is next patterned as by an oxide mask or photorisist only, to define an etch window under only selected portions of the wafer area, for example, the active area or areas, and leaving thicker unetched webs, as in the wafer streets. By initially partially backgrinding the wafer, the thickness to be etched is reduced. However, the partial backgrinding step can be eliminated if desired. The mask is then stripped and a back metal is then deposited on the full wafer back side and into the etched depressions or openings.

By thinning the wafer under the active vertical conduction areas, the R_{DSON} of the ultimately formed MOSFET die is reduced, while the thickened web or unetched portions of the wafer or die provide sufficient strength to the wafer to better resist breakage during handling.

### BRIEF DESCRIPTION OF THE DRAWINGS

FIG. 1 is a cross-section of a portion of a semiconductor wafer after the formation of a junction pattern in its upper surface.

FIG. 2 shows the steps of protecting the upper surface of the wafer, a partial backgrind of the back surface (optional) and an etch of the back surface to reduce the wafer thickness at the active area, leaving a web of thicker silicon for structural strength.

FIG. 3 shows the structure of FIG. 2 after metallizing the etched back surface.

### DETAILED DESCRIPTION OF THE INVENTION

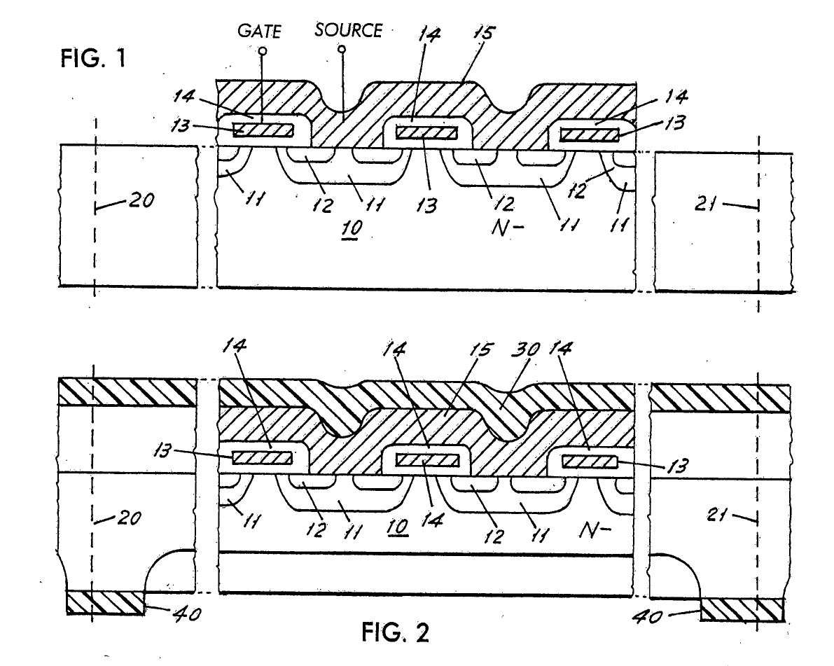

FIG. 1 shows a small portion of a MOSFET wafer or die 10 in which a vertical conduction, planar MOSFET pattern is formed in the top surface of the wafer. Wafer 10 may have a thickness of about 380μ and is easily handled in conventional wafer fabrication equipment. While a planar MOSFET is shown in FIG. 1, the invention applies to trench MOSFETs and planar or trench IGBTs as well.

Wafer 10 is frequently of monocrystaline silicon but other semiconductor materials can employ the invention, such as gallium nitride, silicon carbide and the like.

In FIG. 1, wafer 10 is N⁻ and may have an epitaxially formed top layer to receive the various junctions therein. However, the invention is also applicable to wafers without the epitaxial layer. A plurality of spaced P bases 11 with N⁺ source regions 12 are implanted and diffused into the top surface of wafer 10 using well known processes. Polysilicon gates 13 are formed atop conventional gate oxides and the gates are insulated from source electrode 15 as by LTO oxide 14. Any desired number of base cells or base stripes 11 can be used, and the active areas are ultimately terminated, for each die in the wafer, by a termination region (not shown). All conductivity types can be reversed if desired and other junction patterns can be used. The individual die may then be separated from the wafer at scribe lines 20, 21.

In accordance with the invention, the wafer thickness is reduced to reduce the R_{DSON} component of the drift region of the die in the wafer beneath the level of bases 11, while leaving the wafer sufficiently thick and rugged around the outer periphery of the die to withstand without breaking, the process steps for wafer thinning and the back metal formation process. Alternatively, a plurality of spaced etched areas can be formed in each die in the wafer, thus increasing the die strength.

Thus, as shown in FIG. 2, the top surface of the wafer is covered with a protective layer 30 of tape or the like and the wafer thickness may be initially reduced as by backgrinding to a thickness at which the wafer can still be easily handled, for example, about 150μ (to reduce the amount of silicon which must be removed in a subsequent etch step).

Thereafter, the ground back surface is masked as by an oxide or a photoresist mask 40 alone, and windows are opened in the mask to expose the local backside surfaces under the device active area(s) which are to be exposed to a subsequent silicon etch. However, the street areas containing scribe lines 20 and 21 remain protected against etching. The termination areas may also be protected by the mask 40. Other thickness reduction methods, such as laser ablation, can also be used.

Thereafter, any suitable silicon etch is carried out to reduce the exposed silicon to a thickness of about 80μ or less, thus substantially reducing the device R_{DSON}. However, the thick web remaining at the street (and any other areas of the wafer as desired) retain the necessary wafer strength to permit further processing without excess wafer breakage. While the process is shown for a power MOSFET, this process is also useful to produce Non-Punch-Thru IGBTs and the like.

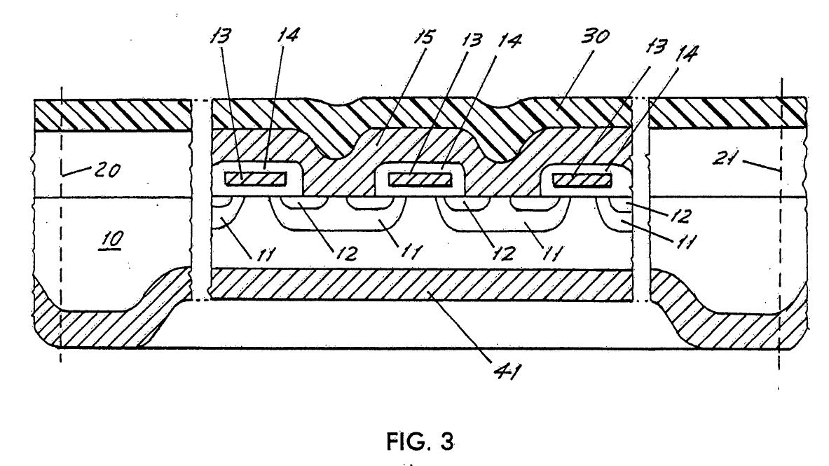

Thereafter, and as shown in FIG. 3, resist 40 is stripped and a back contact metal 41 is formed as by sputtering over the full back surface. Metal 41 can be a tri-metal such as TiNiAg or any other desired metal or alloy. The metal can also fill in the entire etched area to define a fully planar back contact. Note that etched reduced thickness areas can be selectively formed at any desired location over the back area of the die. Thus, in devices which integrate control circuits into the power chip, the etched areas can be disposed under only the power areas of the die.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A power semiconductor device having a reduced R_{DSON} comprising a semiconductor die having top and bottom surfaces, a semiconductor device junction pattern in said top surface, a top main contact connected to said top surface and a bottom main contact connected to said bottom surface; said bottom surface of said die containing at least one reduced thickness area beneath said junction pattern to reduce the length of the current path from said top contact to said bottom contact, thereby to reduce the device R_{DSON}; the thickness of the silicon which is laterally spaced from said reduced thickness area providing increased strength to said die to permit easier handling thereof without fracture.

2. The device of claim 1, wherein said die has a thickness greater than about 150 microns and wherein the reduced thickness area is less than about 80 microns thick.

3. The device of claim 1, wherein said thickness of said region which is laterally spaced from said reduced thickness area surrounds the periphery of said die.

4. The device of claim 1, which further includes a plurality of said reduced thickness areas.

5. The device of claim 1, wherein said semiconductor die is of silicon.

6. The device of claim 1, wherein said semiconductor die is of a material selected from the group consisting of silicon, gallium nitride and silicon carbide.

7. The device of claim 2, wherein said thickness of said region which is laterally spaced from said reduced thickness area surrounds the periphery of said die.

8. The device of claim 2, which further includes a plurality of said reduced thickness areas.

9. The device of claim 2, wherein said semiconductor die is of a material selected from the group consisting of silicon, gallium nitride and silicon carbide.

10. The device of claim 3, which further includes a plurality of said reduced thickness areas.

11. The device of claim 3, wherein said semiconductor die is of a material selected from the group consisting of silicon, gallium nitride and silicon carbide.

12. The device of claim 4, wherein said semiconductor die is of a material selected from the group consisting of silicon, gallium nitride and silicon carbide.

13. The device of claim 1, wherein said die has a thickness which is sufficiently large to permit wafer breakage-free handling and wherein said reduced thickness is too small to permit wafer breakage-free handling if the entire die had said reduced thickness.

14. The device of claim 13, wherein said thickness of said region which is laterally spaced from said reduced thickness area surrounds the periphery of said die.

15. The device of claim 13, which further includes a plurality of said reduced thickness areas.

16. The device of claim 13, wherein said semiconductor die is of a material selected from the group consisting of silicon, gallium nitride and silicon carbide.

17. The process of forming a vertical conduction semiconductor device with a reduced R_{DSON}; said process comprising forming a junction pattern in the top surface of a die of semiconductor material having a thickness greater than about 350 microns; grinding the bottom surface of said die to reduce the thickness of said die to less than about 200 microns but thick enough to withstand handling without fracture; forming at lease one opening into the bottom of said to reduced the thickness of said die above said at least one opening to less than about 80 microns; and forming a bottom electrode over the full bottom surface of said die.
